(19) United States
(12) Patent Application Publication
(10) Pub. No.: US 2025/0392287 A1
(43) Pub. Date: Dec. 25, 2025

(54) HIGH ASPECT RATIO ACOUSTIC RESONATORS

(71) Applicant: Skyworks Solutions, Inc., Irvine, CA (US)

(72) Inventors: Yiliu Wang, Irvine, CA (US); Motoyuki Tajima, Yokohama-Shi (JP); Joji Fujiwara, Suita-Shi (JP)

(21) Appl. No.: 19/248,292

(22) Filed: Jun. 24, 2025

Related U.S. Application Data
(60) Provisional application No. 63/663,913, filed on Jun. 25, 2024.

(51) Int. Cl. H03H 9/64; H03H 9/25; H03H 9/72; H04B 1/00

(52) U.S. Cl. CPC H03H 9/6483; H03H 9/25; H03H 9/725; H04B 1/0057

(57) ABSTRACT

A filter device comprises a transmit filter disposed between a first node and a second node to pass a transmit signal and a receive filter disposed between the second node and the third node to pass a receive signal. At least one of the transmit filter and the receive filter including a high aspect ratio resonator connected to the second node, which can be an antenna port node. The high aspect ratio resonator has an aspect ratio of a length in a propagation direction of the transmit signal or the receive signal and a width in an aperture direction perpendicular to the propagation direction higher than one. The length of the high aspect ratio resonator can be longer than 35 λ, where λ is a wavelength of a resonant frequency of the high aspect ratio resonator.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to filter device for use in radio frequency (RF) electronics.

### Description of the Related Technology

The front end system aids is conditioning signals transmitted to and/or received from the antennas. For example, the front end system includes power amplifiers (PAS), low noise amplifiers (LNAs), filters, switches, and duplexers.

The front end system can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

### SUMMARY

In some aspects, the techniques described herein relate to a filter device including: a first node; a second node; a third node; a transmit filter disposed between the first node and the second node to pass a transmit signal at a transmit band; and a receive filter disposed between the second node and the third node to pass a receive signal at a receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than a predetermined value.

In some aspects, the techniques described herein relate to a filter device wherein the filter device is one of a duplexer, a diplexer, and a multiplexer.

In some aspects, the techniques described herein relate to a filter device wherein the high aspect ratio resonator is directly connected to the second node in series.

In some aspects, the techniques described herein relate to a filter device wherein the second node is coupled to an antenna port.

In some aspects, the techniques described herein relate to a filter device wherein the length of the high aspect ratio resonator is longer than 35 λ, λ being a wavelength of a resonant frequency of the high aspect ratio resonator.

In some aspects, the techniques described herein relate to a filter device wherein the width of the high aspect ratio resonator is longer than 16 λ and shorter than 24 λ, λ being a wavelength of a resonant frequency of the high aspect ratio resonator.

In some aspects, the techniques described herein relate to a filter device wherein each of the transmit filter and the receive filter is a ladder-type band-pass filter.

In some aspects, the techniques described herein relate to a filter device wherein the high aspect ratio resonator includes a thin film surface acoustic wave resonator.

In some aspects, the techniques described herein relate to a radio frequency module including: a packaging board configured to receive a plurality of components; a filter device implemented on the packaging board, the filter device including: a first node; a second node; a third node; a transmit filter disposed between the first node and the second node to pass a transmit signal at a transmit band; and a receive filter disposed between the second node and the third node to pass a receive signal at a receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than a predetermined value.

In some aspects, the techniques described herein relate to a radio frequency module wherein the radio frequency module is a front-end module.

In some aspects, the techniques described herein relate to a radio frequency module wherein the filter device is one of a duplexer, a diplexer, and a multiplexer.

In some aspects, the techniques described herein relate to a radio frequency module wherein the high aspect ratio resonator is directly connected to the second node in series.

In some aspects, the techniques described herein relate to a radio frequency module wherein the second node is coupled to an antenna port.

In some aspects, the techniques described herein relate to a radio frequency module wherein the length of the high aspect ratio resonator is longer than 35 λ, λ being a wavelength of a resonant frequency of the high aspect ratio resonator.

In some aspects, the techniques described herein relate to a radio frequency module wherein the width of the high aspect ratio resonator is longer than 16 λ and shorter than 24 λ, λ being a wavelength of a resonant frequency of the high aspect ratio resonator.

In some aspects, the techniques described herein relate to a radio frequency module wherein each of the transmit filter and the receive filter is a ladder-type band-pass filter.

In some aspects, the techniques described herein relate to a radio frequency module wherein the high aspect ratio resonator includes a thin film surface acoustic wave resonator.

In some aspects, the techniques described herein relate to a mobile device including: a transceiver configured to generate a transmit signal and to process a receive signal; and a filter device including: a first node; a second node; a third node; a transmit filter disposed between the first node and the second node to pass a transmit signal at a transmit band; and a receive filter disposed between the second node and the third node to pass a receive signal at an receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than a predetermined value.

In some aspects, the techniques described herein relate to a mobile device wherein the filter device is one of a duplexer, a diplexer, and a multiplexer.

In some aspects, the techniques described herein relate to a mobile device wherein the high aspect ratio resonator is directly connected to the second node in series.

In some aspects, the techniques described herein relate to a mobile device wherein the second node is coupled to an antenna port.

In some aspects, the techniques described herein relate to a mobile device wherein the length of the high aspect ratio resonator is longer than 35 λ, λ being a wavelength of a resonant frequency of the high aspect ratio resonator.

In some aspects, the techniques described herein relate to a mobile device wherein the width of the high aspect ratio resonator is longer than 16 λ and shorter than 24 λ, λ being a wavelength of a resonant frequency of the high aspect ratio resonator.

In some aspects, the techniques described herein relate to a mobile device wherein each of the transmit filter and the receive filter is a ladder-type band-pass filter.

In some aspects, the techniques described herein relate to a mobile device wherein the high aspect ratio resonator includes a thin film surface acoustic wave resonator.

### BRIEF DESCRIPTION OF THE DRAWINGS

FIG. 1 is a schematic diagram of one embodiment of a mobile device.

FIG. 2 is a block diagram of a front-end module;

FIG. 3 is a block diagram of an antenna switching module arrangement;

FIG. 4 illustrates a wireless device having a primary antenna and a diversity antenna.

FIG. 5 illustrates a wireless device that incorporates some or all of the configurations described herein.

FIG. 6A is a schematic diagram of a filter device according to the present disclosure, including at least one high aspect ratio (AR) resonator.

FIG. 6B is a schematic diagram of an example of a high AR resonator.

FIG. 6C is a schematic plan view showing examples high AR surface acoustic wave resonators.

FIG. 6D is a schematic cross-sectional side view of the high AR acoustic resonators of FIG. 6C. FIGS. 6B-6D are not drawn to scale.

FIG. 7A shows a simulation result of measuring an admittance (Y) of a high AR resonator according to the present disclosure.

FIG. 7B shows a simulation result of measuring a conductance (G) of a high AR resonator according to the present disclosure.

FIG. 7C shows a simulation result of measuring a Bode Q of a high AR resonator according to the present disclosure.

FIG. 8A shows a simulation result of measuring in-band TX performance of a filter device with high AR resonator according to the present disclosure.

FIG. 8B shows a simulation result of measuring in-band RX performance of a filter device with high AR resonator according to the present disclosure.

FIG. 8C shows a simulation result of measuring a TX insertion loss (IL) of a filter device with high AR resonator according to the present disclosure.

FIG. 8D shows a simulation result of measuring a RX insertion loss (IL) of a filter device with high AR resonator according to the present disclosure.

FIG. 9A shows another simulation result of measuring in-band TX performance of a filter device with high AR resonator according to the present disclosure.

FIG. 9B shows another simulation result of measuring in-band RX performance of a filter device with high AR resonator according to the present disclosure

FIG. 9C shows another simulation result of measuring a TX insertion loss (IL) of a filter device with high AR resonator according to the present disclosure.

FIG. 9D shows another simulation result of measuring a RX insertion loss (IL) of a filter device with high AR resonator according to the present disclosure

FIG. 10B is a schematic diagram of a cross-section of the packaged module of FIG. 10A taken along the lines 10B-10B.

FIG. 11 is a schematic diagram of one embodiment of a phone board.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

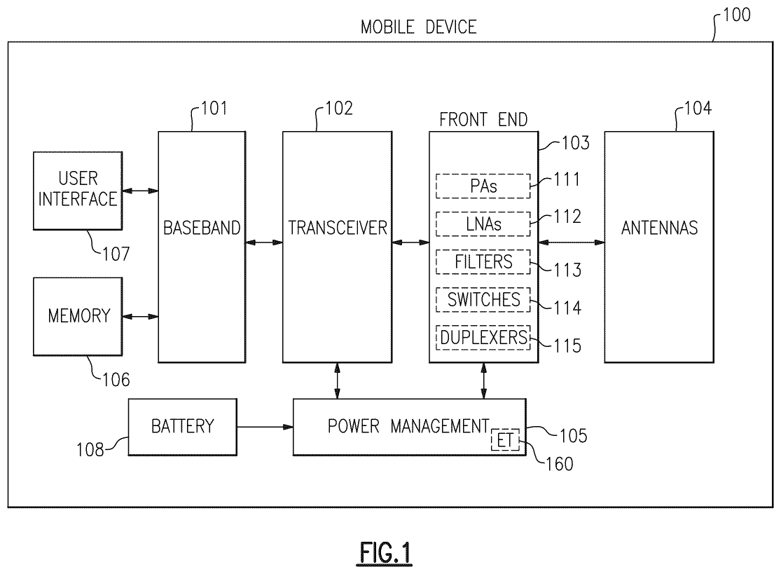

FIG. 1 is a schematic diagram of one example of a mobile device 100. The mobile device 100 includes a baseband system 101, a transceiver 102, a front end system 103, antennas 104, a power management system 105, a memory 106, a user interface 107, and a battery 108.

The mobile device 100 can be used communicate using a wide variety of communications technologies, including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies.

The transceiver 102 generates RF signals for transmission and processes incoming RF signals received from the antennas 104. It will be understood that various functionalities associated with the transmission and receiving of RF signals can be achieved by one or more components that are collectively represented in FIG. 1 as the transceiver 102. In one example, separate components (for instance, separate circuits or dies) can be provided for handling certain types of RF signals.

The front end system 103 aids is conditioning signals transmitted to and/or received from the antennas 104. In the illustrated embodiment, the front end system 103 includes power amplifiers (PAs) 111, low noise amplifiers (LNAs) 112, filters 113, switches 114, and duplexers 115. However, other implementations are possible.

For example, the front end system 103 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 100 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band and/or in different bands.

The antennas 104 can include antennas used for a wide variety of types of communications. For example, the antennas 104 can include antennas associated transmitting and/or receiving signals associated with a wide variety of frequencies and communications standards.

In certain implementations, the antennas 104 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 100 can operate with beamforming in certain implementations. For example, the front end system 103 can include phase shifters having variable phase controlled by the transceiver 102. Additionally, the phase shifters are controlled to provide beam formation and directivity for transmission and/or reception of signals using the antennas 104. For example, in the context of signal transmission, the phases of the transmit signals provided to the antennas 104 are controlled such that radiated signals from the antennas 104 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 104 from a particular direction. In certain implementations, the antennas 104 include one or more arrays of antenna elements to enhance beamforming.

The baseband system 101 is coupled to the user interface 107 to facilitate processing of various user input and output (I/O), such as voice and data. The baseband system 101 provides the transceiver 102 with digital representations of transmit signals, which the transceiver 102 processes to generate RF signals for transmission. The baseband system 101 also processes digital representations of received signals provided by the transceiver 102. As shown in FIG. 1, the baseband system 101 is coupled to the memory 106 of facilitate operation of the mobile device 100.

The memory 106 can be used for a wide variety of purposes, such as storing data and/or instructions to facilitate the operation of the mobile device 100 and/or to provide storage of user information.

The power management system 105 provides a number of power management functions of the mobile device 100. The power management system 105 of FIG. 1 includes an envelope tracker 160. As shown in FIG. 1, the power management system 105 receives a battery voltage form the battery 1008. The battery 108 can be any suitable battery for use in the mobile device 100, including, for example, a lithium-ion battery.

The mobile device 100 of FIG. 1 illustrates one example of an RF communication system that can include low noise amplifier(s) implemented in accordance with one or more features of the present disclosure. However, the teachings herein are applicable to RF communication systems implemented in a wide variety of ways.

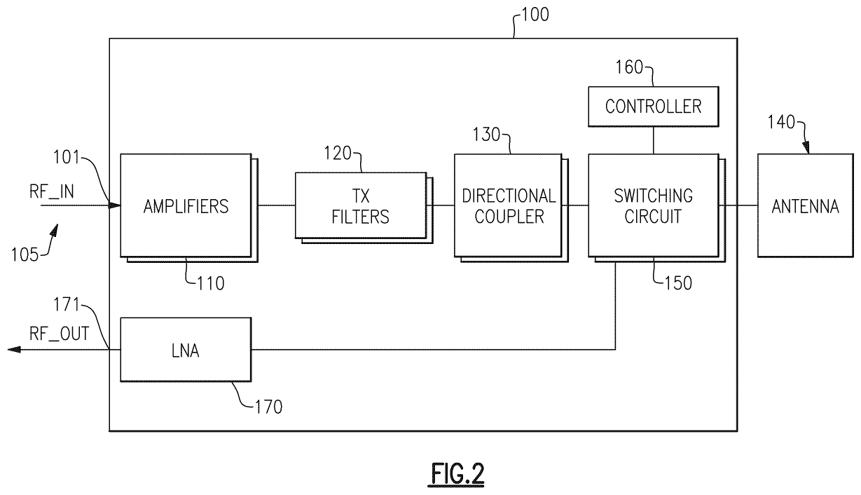

FIG. 2 is a block diagram illustrating an example of a typical arrangement of a radio-frequency (RF) “front-end” sub-system or module (FEM) 200 as may be used in a communications device, such as a mobile phone, for example, to transmit and receive RF signals. The FEM 200 shown in FIG. 2 includes a transmit path (TX) configured to provide signals to an antenna for transmission and a receive path (RX) to receive signals from the antenna. In the transmit path (TX), a power-amplifier module 210 provides gain to an RF signal 205 received by the FEM 200 via an input port 201, producing an amplified RF signal. The power amplifier module 210 can include one or more power amplifiers (PAs), or “amplifiers.”

The FEM 200 can further include a filtering sub-subsystem or module 220, which can include one or more filters. In some examples, a directional coupler 230 can be used to extract a portion of the power from the RF signal traveling between the power-amplifier module 210 and an antenna 240 connected to the FEM 200. The antenna 240 can transmit the RF signal and can also receive RF signals. A switching circuit 250, also referred to as an antenna switch module (ASM), can be used to switch between a transmitting mode and receiving mode of the FEM 200, for example, or between different transmit or receive frequency bands. In certain examples, the switching circuit 250 can be operated under the control of a controller 260.

The FEM 200 can also include a receive path (RX) configured to process signals received by the antenna 240 and provide the received signals to a signal processor (e.g., a transceiver) via an output port 271. The receive path (RX) can include one or more low- noise amplifiers (LNA) 270 to amplify the signals received from the antenna 240. Although not shown, the receive path (RX) can also include one or more filters for filtering the received signals.

As described above, antenna switching modules (e.g., switching circuit 250) can be used in front end module (FEM) products, such as radio transceivers, wireless handsets, and the like. In one example, the ASM is configured to connect the antenna to either the transmit path (TX) or the receive path (RX) depending on the mode of operation. In some examples, the ASM may be coupled to multiple duplexers for multi-band applications.

FIG. 3 is a schematic diagram of an ASM arrangement 300. In one example, the ASM arrangement 300 may be included in a FEM (e.g., the FEM 200 of FIG. 2). The ASM arrangement 200 includes an ASM 202, a plurality of duplexers 204, and a plurality of shunt inductors 306. As shown, the ASM 302 includes a plurality of transmit/receive (T/R) terminals 308 coupled to the plurality of duplexers 304. For example, the first input 308 a is coupled to the first duplexer 304 a, the second input 308 b is coupled to the second duplexer 304 b, and so on. In some examples, the ASM 302 includes an antenna terminal 310 coupled to an antenna 312. In this context, the term “terminal” may be used interchangeably with “port” or “pin”.

In one example, each of the plurality of duplexers 304 is coupled to a pair of receive (RX) and transmit (TX) paths. Each duplexer of the plurality of duplexers 304 may include switching, coupling, and/or filtering circuitry configured to direct radio frequency (RF) signals to/from the respective receive (RX) and transmit (TX) paths. In some examples, the ASM 302 can be operated or controlled in different modes of operation to connect each of the plurality of duplexers 304 to the antenna 312 (via the antenna terminal 310). For example, in a first mode of operation, the ASM 302 can be controlled to connect the first duplexer 304 a to the antenna 312 by coupling the first T/R terminal 308 a to the antenna terminal 310. As such, during the first mode of operation, RF signals received by the antenna 312 are provided to the receive (RX) path coupled to the first duplexer 304 a. Likewise, during the first mode of operation, RF signals provided by the transmit (TX) path coupled to the first duplexer 304 a can be transmitted by the antenna 312. Similarly, in a second mode of operation, the ASM 302 can be controlled to connect the second duplexer 304 b to the antenna 312 by coupling the second T/R terminal 308 b to the antenna terminal 310, and so on.

In some examples, each duplexer of the plurality of duplexers 304 corresponds to a specific frequency or frequency band. For example, the first duplexer 304 a and the receive (RX) and transmit (TX) paths coupled to the first duplexer 304 a may correspond to a first frequency or frequency band. As such, the ASM 302 can be controlled to operate in the first mode of operation when transmitting/receiving RF signals corresponding to the first frequency (or frequency band). Likewise, the second duplexer 304 b and the receive (RX) and transmit (TX) paths coupled to the second duplexer 304 b may correspond to a second frequency or frequency band and the ASM 302 can be controlled to operate in the second mode of operation when transmitting/receiving RF signals corresponding to the second frequency (or frequency band), and so on.

In order to provide optimal performance (e.g., low loss) at each frequency (or frequency band), the resonant frequency of each duplexer (and the respective RX, TX paths) may be tuned or adjusted via impedance matching. In one example, the plurality of shunt inductors 306 are coupled between the plurality of duplexers 304 and the plurality of inputs 308 to provide an impedance match during each mode of operation. For example, the first shunt inductor 306 a is configured to adjust the impedance of the first duplexer 304 a and the receive (RX) and transmit (TX) paths coupled to the first duplexer 304 a to provide a resonant frequency at the first frequency (or frequency band) during the first mode of operation. Likewise, the second shunt inductor 306 b is configured to adjust the impedance of the second duplexer 304 b and the receive (RX) and transmit (TX) paths coupled to the second duplexer 304 b to provide a resonant frequency at the second frequency (or band) during the second mode of operation, and so on.

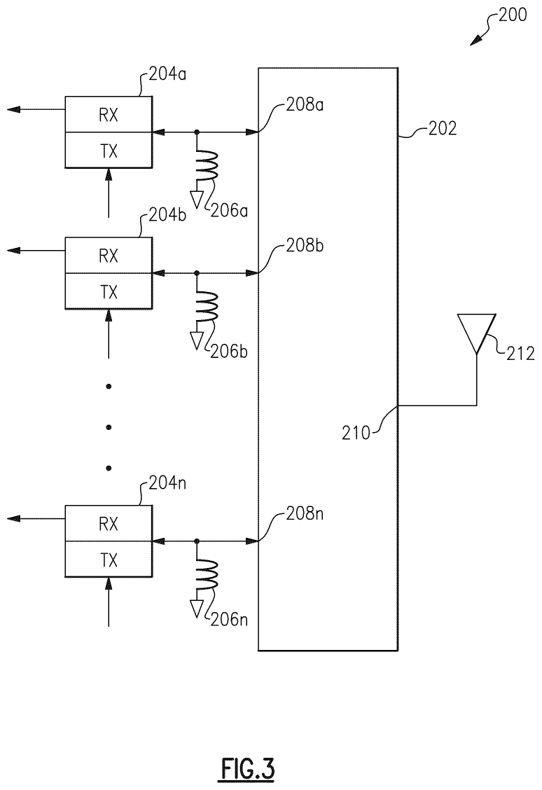

FIG. 4 illustrates a wireless device 400 having a primary antenna 402 a and a diversity antenna 402 b. The wireless device 400 includes an RF module 496 and a transceiver 494 that may be controlled by a controller 492. The transceiver 494 is configured to convert between analog signals (e.g., radio-frequency (RF) signals) and digital data signals. To that end, the transceiver 494 may include a digital-to-analog converter, an analog-to-digital converter, a local oscillator for modulating or demodulating a baseband analog signal to or from a carrier frequency, a baseband processor that converts between digital samples and data bits (e.g., voice or other types of data), or other components.

The RF module 496 is coupled between the primary antenna 402 a and the transceiver 494. Because the RF module 496 may be physically close to the primary antenna 402 a to reduce attenuation due to cable loss, the RF module 496 may be referred to as a front-end module (FEM). The RF module 496 may perform processing on an analog signal received from the primary antenna 402 a for the transceiver 494 or received from the transceiver 494 for transmission via the primary antenna 402 a. To that end, the RF module 496 includes an antenna switch module (ASM) 430 a, one or more duplexers 420 a, one or more amplifiers 460 a (including power amplifiers (PAs) and low noise amplifiers (LNAs)) and may also include amplifier switches, band select switches, attenuators, matching circuits, multiplexers, and other components. The ASM 430 a may be connected to a plurality of duplexers 420 a to enable operation across a plurality of frequency bands. A signal for transmission can be sent from the transceiver 494 through the RF module 496, being amplified by an amplifier 460 a (e.g., a PA), filtered by a duplexer 420 a, and coupled to the primary antenna 402 a via the ASM 430 a. A signal received at the antenna 402 a can be sent through the RF module 496, being connected to a duplexer 420 a via the ASM 430 a, being filtered by the duplexer 420 a, and being amplified by an amplifier 460 a (e.g., a LNA) before being sent to the transceiver 494.

FIG. 5 depicts an example wireless device 500 having one or more advantageous features described herein. In the context of one or more modules having one or more features as described herein, such modules can be generally depicted by a dashed box 506 (which can be implemented as, for example, a front-end module) and a diversity receiver (DRx) module 508 (which can be implemented as, for example, a front-end module).

Referring to FIG. 5, power amplifiers (PAS) 582 can receive their respective RF signals from a transceiver 504 that can be configured and operated to generate RF signals to be amplified and transmitted, and to process received signals. The transceiver 504 is shown to interact with a baseband sub-system 505 that is configured to provide conversion between data and/or voice signals suitable for a user and RF signals suitable for the transceiver 504. The transceiver 504 can also be in communication with a power management component 507 that is configured to manage power for the operation of the wireless device 500. Such power management can also control operations of the baseband sub-system 505 and the modules 506 and 508.

The baseband sub-system 505 is shown to be connected to a user interface 501 to facilitate various input and output of voice and/or data provided to and received from the user. The baseband sub-system 505 can also be connected to a memory 503 that is configured to store data and/or instructions to facilitate the operation of the wireless device, and/or to provide storage of information for the user.

In the example wireless device 500, outputs of the PAs 582 are shown to be routed to their respective duplexers 586. The duplexers 586 can be configured as described herein to conglomerate TX contours to remove matching components between the PAs 582 and the duplexers 586. Such amplified and filtered signals can be routed to a primary antenna 560 through a switching network 509 for transmission. In some embodiments, the duplexers 586 can allow transmit and receive operations to be performed simultaneously using a common antenna (e.g., primary antenna 560). In FIG. 5, received signals are routed to low-noise amplifiers (not shown).

The wireless device also includes a diversity antenna 570 and a diversity receiver module 508 that receives signals from the diversity antenna 570. The diversity receiver module 508 processes the received signals and transmits the processed signals to the transceiver 504. In some embodiments, a diplexer, triplexer, or other multiplexer or filter assembly can be included between the diversity antenna 570 and the diversity receiver module 570, as described herein.

For filter applications, better insertion loss (IL), and improved power handling are required. At the same time, module size reduction is a never-ending request from the customers. As filters take more area than any other components in the FEM, to get the IL and ruggedness improvement with similar or smaller size is necessary.

In order to improved ruggedness of the resonator, resonator series cascade could be used. In addition, improved piston mode design can be used to remove the transverse mode and to improve the insertion loss. Furthermore, a layout was suggested to find heat leak path from the Tx heat sources.

Hereinafter, a filter device according to the present disclosure is introduced to boost the Q below Fs of the resonator. Particularly, for BPF (ladder type), series resonator with high aspect ratio (AR) resonator will improve the low/mid channel insertion loss (IL). The aspect ratio (AR) can be defined as follows:
AR: Propagation direction length (L) vs aperture direction width (A).
AR=L/A (long side over short side)

More specifically, according to the present disclosure, connect the routing

on the long side of the resonator will help the heat dissipation from the resonator center to its perimeter, enhancing the power handling.

To get good conductance floor (dB_real_Y) from the resonator at the Ant port (refer to the below topology, so that gamma loading to the CA (carrier aggregation) bands (in band frequency also falls into the frequency below Fs region) are reduced for performance improvement.

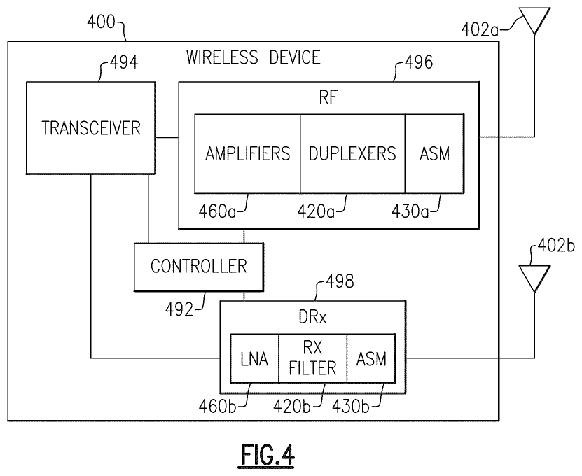

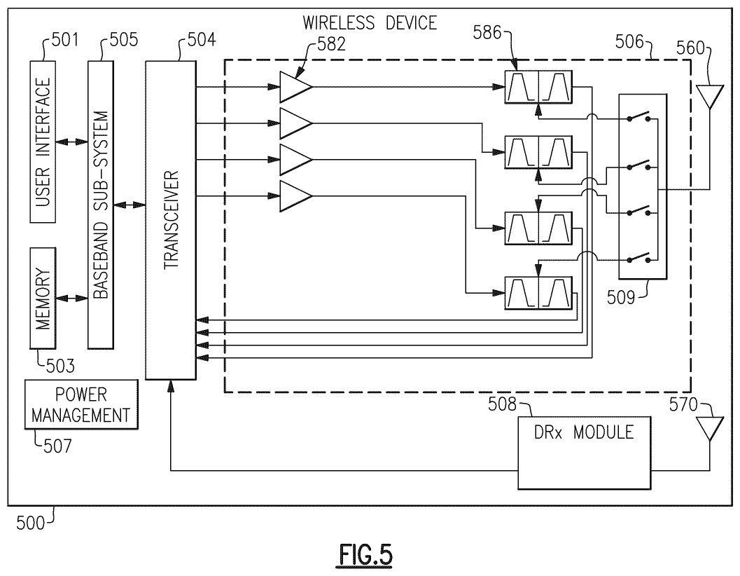

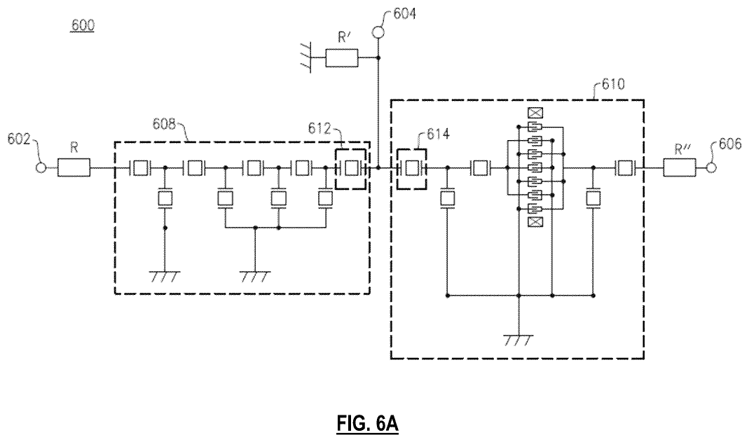

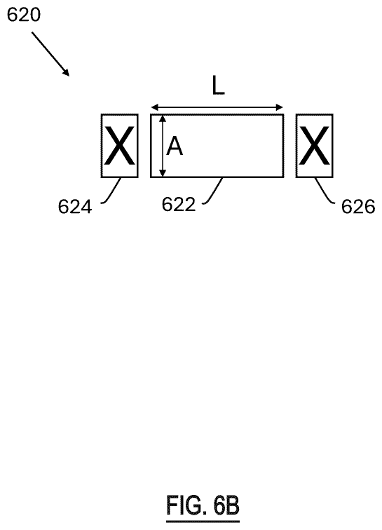

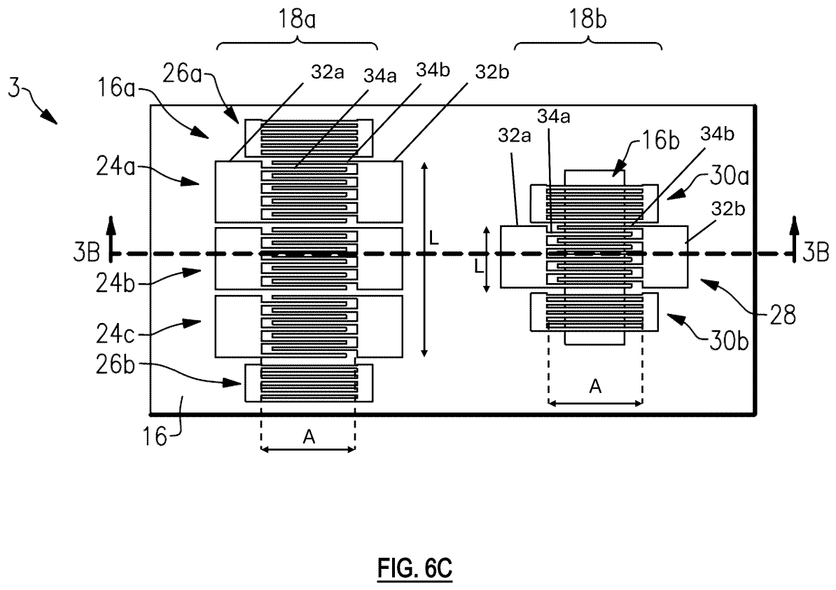

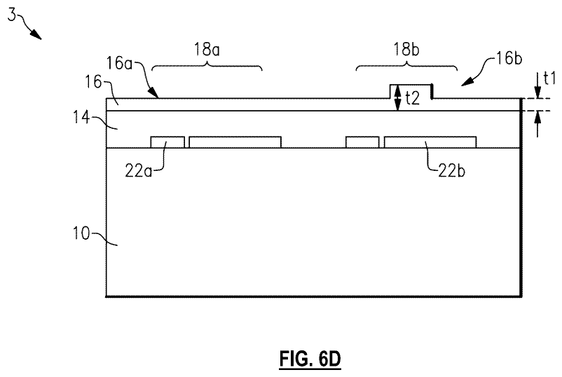

FIG. 6A is a schematic diagram of a filter device 600 according to the present disclosure. The filter device 600 according to the present disclosure may be one of a duplexer, a diplexer, or a multiplexer.

As shown in FIG. 6A, the filter device 600 may include a first node 602, a second node 604, and a third node 606. The first node 602 may be a transmission (TX) node configured to receive a TX signal from, for example, a transceiver (not shown in FIG. 6A). The second node 604 may be an antenna node suitable for being connected to an antenna (not shown). The third node 606 may be a reception (RX) node configured to transmit a RX signal to, for example, the transceiver.

The filter device 600 may further include a TX filter 608 disposed between the first node 602 and the second node 604. The TX filter 608 may be configured to pass a TX signal at a TX band. According to an embodiment, the TX band may have a frequency range of 880-915 MHz.

The filter device 600 may further include a RX filter 610 disposed between the second node 604 and the third node 606. The RX filter 610 may be configured to pass an RX signal at an RX band. According to an embodiment, the RX band may have a frequency range of 925-960 MHz.

At least one of the TX filter 608 and the RX filter 610 may include a high aspect ratio (AR) resonator 612, 614. For example, the TX filter 608 may include the high AR resonator 612, while the RX filter 610 may not have. Or, the RX filter 610 may include the high AR resonator 614, while the TX filter 608 may not have. Or, both the TX filter 608 and the RX filter 610 may include the high AR resonators 612, 614, respectively. The high AR resonator may be made of a thin film SAW.

Each of the high AR resonators 612, 614 may have its own aspect ratio. The aspect ratio can be defined as a ratio of a length (L) in a propagation direction of the TX signal or the RX signal and a width (A) in an aperture direction perpendicular to the propagation direction. According to an embodiment of the present disclosure, the high AR resonators 612, 614 may have the aspect ratio higher than a predetermined value. For example, the length L of the high AR resonator may be longer than 35 λ (e.g. 35.01, 35.1, 36, 37, 38, 39, 40, 45, 50 or longer), and the width A of the high AR resonator may be longer than 16 λ and shorter than 24 λ (λ is a wavelength of a resonant frequency of the high AR resonator). In this example, the predetermined value may be approximately 1.458. In other embodiments, the predetermined value can be any value from 1.458 (35/24) to 2.188 (35/16), can be greater than any of 1, 1.2, 1.3, 1.4, 1.5, 1.75, 2, 2.25 2.5, 2.75, 3, or 4, or can be between any of these values.

As shown in FIG. 6A, the high AR resonators 612, 614 may be disposed to be directly connected to the second node 604 in series. That is, each of the high AR resonators 612, 614 may be a series resonator. According to an embodiment of the present disclosure, each of the high AR resonators 612, 614 may be a ladder-type band-pass filter or resonator.

According to the embodiments of the present disclosure, a good conductance floor from the resonator at the antenna port can be achieved such that gamma loading to the carrier aggregation (CA) band, for example, below Fs, is reduced for performance improvement. For example, including high AR resonators 612, 614 proximate to or directly connected to the antenna port can result in these and other advantages.

FIG. 6B is a plan view of a schematic diagram of an example of a high AR resonator 620. The propagation direction length (L) of the resonator 620 can be the distance between the reflectors 624, 626, which can also be the length of a resonance cavity 622, which can include one or more interdigital transducers (not shown). The aperture direction width (A) of the resonator 620 can be the width of the acoustic cavity 622 in a direction perpendicular to the propagation direction length L. The AR can be L/A. For example, L can be larger than A.

Any of the high AR resonators described herein can be the high AR resonator 620. For example, the high AR resonators 612, 614 of FIG. 6A may be the AR resonator 620 of FIG. 6B.

FIG. 6C is a schematic top plan view of an example of a high AR acoustic wave device 3. FIG. 6D is a schematic cross-sectional side view of the acoustic wave device 3 of FIG. 6C. The dimensions are not drawn to scale. The acoustic wave device 3 can be an acoustic wave filter for filtering a radio frequency signal. The acoustic wave device 3 can include a piezoelectric layer 10, a first resonator 22a, a second resonator 22b, a temperature compensation layer 14, and a passivation layer 16.

The first resonator 22a can be a DMS resonator and the second resonator 22b can be a one-port resonator. The first resonator 22a can include a first interdigital transducer (IDT) electrode 24a, a second IDT electrode 24b, a third IDT electrode 24c, and a pair of reflectors 26a, 26b that are longitudinally coupled along a wave propagation direction of the first resonator 22a. The second resonator 22b can include an IDT electrode 28 and a pair of reflectors 30a, 30b. The IDT electrode 28 is positioned between the pair pf reflectors 30a, 30b.

The IDT electrodes (e.g., the first to third IDT electrodes 24a-24c and the IDT electrode 28) can include any suitable IDT electrode material. For example, the IDT electrodes can include molybdenum (Mo), aluminum (Al), copper (Cu), Magnesium (Mg), titanium (Ti), tungsten (W), the like, or any suitable combination thereof. The IDT electrodes can have a multilayer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The interdigital transducer electrodes can be formed with (e.g., formed on or at least partially in) the piezoelectric layer 10. The piezoelectric layer 10 and the interdigital transducer electrodes can be provided in any suitable manner. For example, the piezoelectric layer 10 and the interdigital transducer electrodes can be provided in sequence. When the interdigital transducer electrodes are provided at least partially in the piezoelectric layer 10, the piezoelectric layer 10 can be partially etched and/or provided in a plurality of steps.

The IDT electrode 28 of the second resonator 22b and each of the IDT electrodes 24a, 24b, 24c of the first resonator 22a can each include a first bus bar 32a, a first set of fingers 34a extending from the first bus bar 32a, a second bus bar 32b, and a second set of fingers extending 34b from the second bus bar 32b. The IDT electrode 28 and the IDT electrodes 24a, 24b, 24c can each include a first gap region between the first set of fingers 34a and the second bus bar 32b and a second gap region between the second set of fingers 34b and the first bus bar 32a. The IDT electrode 28 and the IDT electrodes 24a, 24b, 24c can each include an active region between the first and second gap regions. The active region can include a center region, a first border region between the center region and the first gap region, and a second border region between the center region and the second gap region.

The passivation layer 16 has a first portion 16a in the first region 18a and a second portion 16b in the second region 18b. The first portion 16a can at least partially overlap the first resonator 22a and the second portion 16b can at least partially overlap the second resonator 22b. The location of the second portion 16b can contribute to suppressing the SH mode spur from the second resonator 22b. In some embodiments, the second portion 16b can at least overlap the center region of the IDT electrode 28.

As shown, the propagation direction length L can be the distance between the reflectors 26a, 26b for the first resonator 22a and the distance between the reflectors 30a, 30b for the second resonator 22b. The aperture direction width W extends between the inner edges of the opposing busbars 32a, 32b according to the illustrated embodiment. In other embodiments, the aperture direction width W can be defined as any of the active region between the first and second gap regions, the region of overlap of the fingers 34a, 34b of the opposing bus bars, or the length of the fingers 34a, 34b extending from the first bus bar 32a and/or the second bus bar 32b.

FIGS. 6B, 6C and 6D are not drawn to scale. For example, while the aperture direction width A of the second resonator 22b of FIGS. 6C, 6D may appear larger than the propagation direction length L of the second resonator 22b, the drawing is not to scale, and according to embodiments, the length L can actually be larger than the width A for both the first and second resonators 22a, 22b of FIGS. 6C and 6D.

Any of the high AR resonators described herein can be the first high AR resonator 22a or the second high AR resonator 22b. For example, the high AR resonators 612, 614 of FIG. 6A may be the first AR resonator 22a or the second AR resonator 22b.

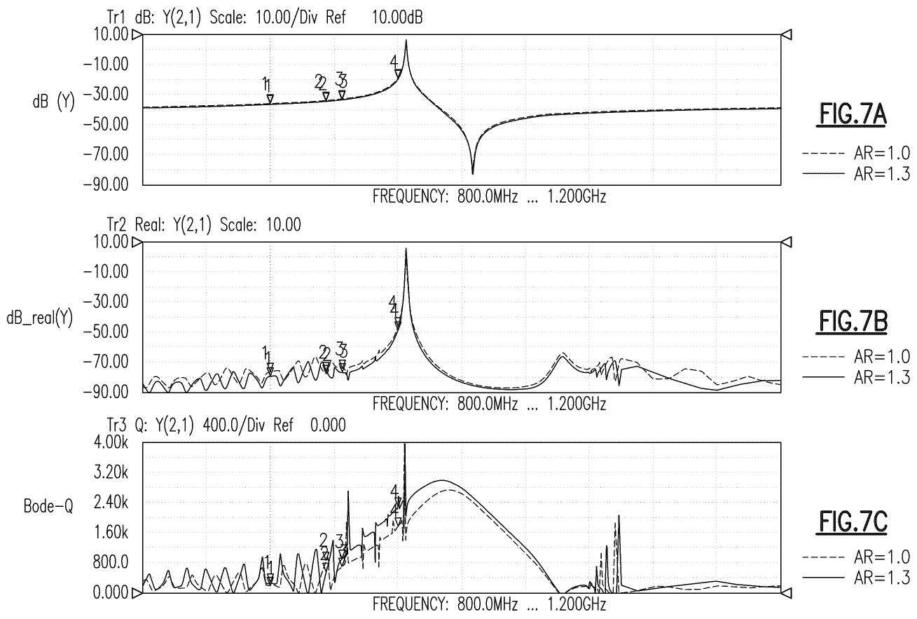

FIG. 7A shows a simulation result of measuring an admittance (Y) of a high AR resonator according to the present disclosure. FIG. 7B shows a simulation result of measuring a conductance (G) of a high AR resonator according to the present disclosure. FIG. 7C shows a simulation result of measuring a Bode Q of a high AR resonator according to the present disclosure. In this exemplary simulation, the TX band is 880-915 MHz, and the RX band is 925-960 MHz.

As shown in FIGS. 7A-7C, the parameters of the high AR resonator with AR of 1.3 at frequency below Fss are improved compared to a less high AR resonator with AR of 1.0. Particularly, with narrow aperture, Q below Fs can be improved. According to an embodiment, in case only RX filter includes the high AR resonator, Q below Fs is improved not only the RX filter itself, but also the TX loading is reduced, and therefore the TX performance is improved. In other words, the RX filter having the high AR resonator may help the TX filter to improve its performance.

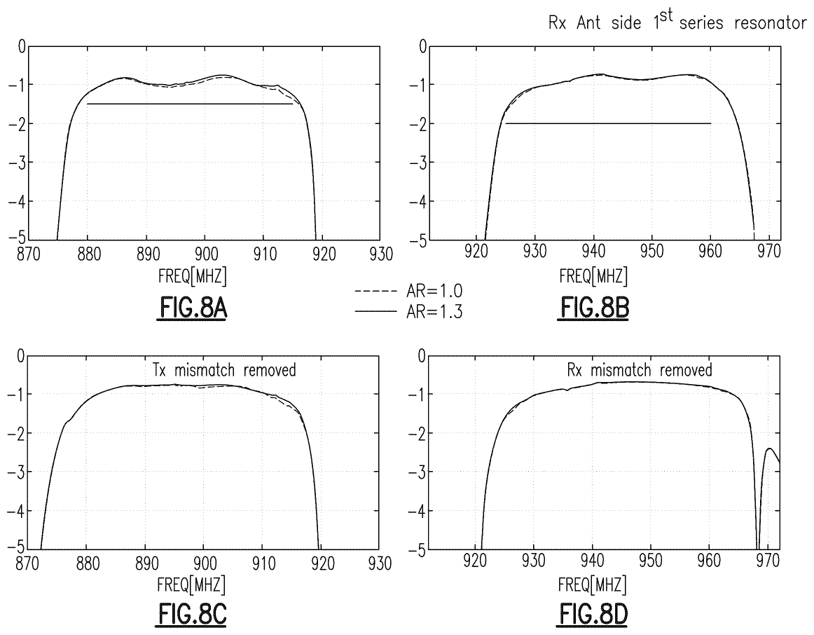

FIG. 8A shows a simulation result of measuring in-band TX performance of a filter device with high AR resonator according to the present disclosure. FIG. 8B shows a simulation result of measuring in-band RX performance of a filter device with high AR resonator according to the present disclosure. In FIGS. 8A-8B, the filter with Rx antenna side 1^{st} series resonator having AR of 1.3 has better performance than the other filter with RX antenna side 1^{st} series resonator having AR of 1.0. The Rx antenna side 1^{st} series resonator contributes to the improvement not only for the RX performance but also for the TX performance.

FIG. 8C shows a simulation result of measuring a TX insertion loss (IL) of a filter device with high AR resonator according to the present disclosure. FIG. 8D shows a simulation result of measuring a RX insertion loss (IL) of a filter device with high AR resonator according to the present disclosure. As can be seen from FIGS. 8C-8D, the RX/TX mismatches of the filter device with higher AR (1.3) are improved across the respective bands, compared to the filter with less higher AR (1.0).

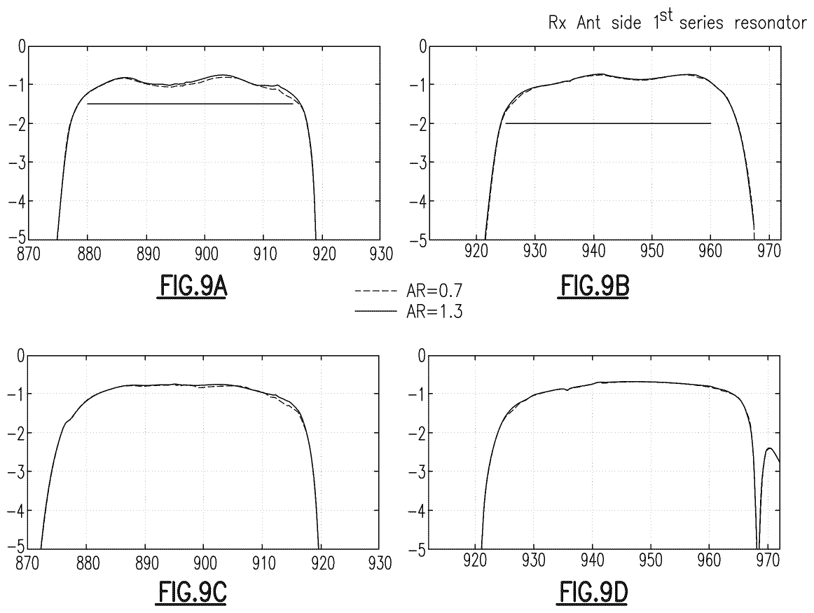

FIG. 9A shows another simulation result of measuring in-band TX performance of a filter device with high AR resonator according to the present disclosure. FIG. 9B shows another simulation result of measuring in-band RX performance of a filter device with high AR resonator according to the present disclosure. In FIGS. 9A-9B, the filter with Rx antenna side 1^{st} series resonator having AR of 1.3 has better performance than the other filter with RX antenna side 1^{st} series resonator having AR of 0.7. The Rx antenna side 1^{st} series resonator contributes to the improvement not only for the RX performance but also for the TX performance.

FIG. 9C shows another simulation result of measuring a TX insertion loss (IL) of a filter device with high AR resonator according to the present disclosure. FIG. 9D shows another simulation result of measuring a RX insertion loss (IL) of a filter device with high AR resonator according to the present disclosure. As can be seen from FIGS. 9C-9D, the RX/TX mismatches of the filter device with higher AR (1.3) are improved across the respective bands, compared to the filter with less higher AR (0.7).

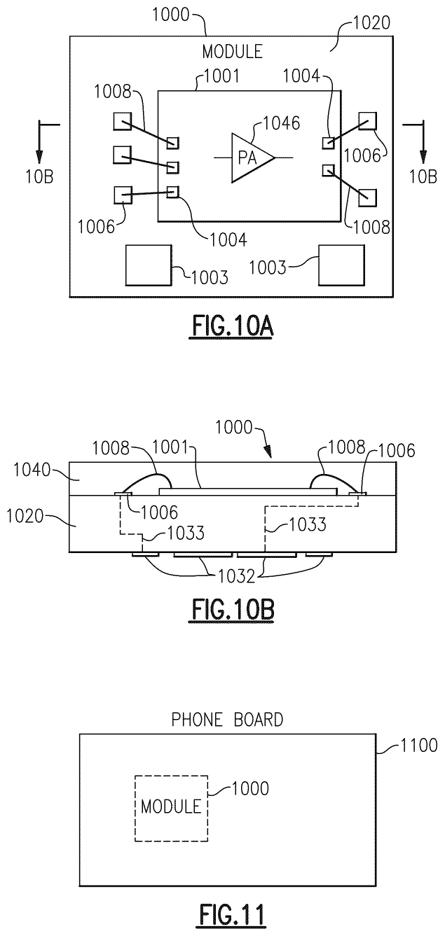

FIG. 10A is a schematic diagram of one embodiment of a packaged module 900. FIG. 10B is a schematic diagram of a cross-section of the packaged module 1000 of FIG. 10A taken along the lines 10A-10B.

The packaged module 1000 includes an IC or die 1001, surface mount components 1003, wirebonds 1008, a package substrate 1020, and encapsulation structure 1040. The package substrate 1020 includes pads 1006 formed from conductors disposed therein. Additionally, the die 1001 includes pads 1004, and the wirebonds 1008 have been used to electrically connect the pads 1004 of the die 1001 to the pads 1006 of the package substrate 1020.

The package module 1000 includes a low noise amplifier 1046, which can be implemented in accordance with any of the embodiments herein.

The packaging substrate 1020 can be configured to receive a plurality of components such as the die 1001 and the surface mount components 1003, which can include, for example, surface mount capacitors and/or inductors.

As shown in FIG. 10B, the packaged module 1000 is shown to include a plurality of contact pads 1032 disposed on the side of the packaged module 1000 opposite the side used to mount the die 1001. Configuring the packaged module 1000 in this manner can aid in connecting the packaged module 1000 to a circuit board such as a phone board of a wireless device. The example contact pads 1032 can be configured to provide RF signals, bias signals, power low voltage(s) and/or power high voltage(s) to the die 1001 and/or the surface mount components 1003. As shown in FIG. 10B, the electrically connections between the contact pads 1032 and the die 1001 can be facilitated by connections 1033 through the package substrate 1020. The connections 1033 can represent electrical paths formed through the package substrate 1020, such as connections associated with vias and conductors of a multilayer laminated package substrate.

In some embodiments, the packaged module 1000 can also include one or more packaging structures to, for example, provide protection and/or facilitate handling of the packaged module 1000. Such a packaging structure can include overmold or encapsulation structure 1040 formed over the packaging substrate 1020 and the components and die(s) disposed thereon.

It will be understood that although the packaged module 1000 is described in the context of electrical connections based on wirebonds, one or more features of the present disclosure can also be implemented in other packaging configurations, including, for example, flip-chip configurations.

FIG. 11 is a schematic diagram of one embodiment of a phone board 1100. The phone board 1100 includes the module 1000 shown in FIGS. 10A-10B attached thereto. Although not illustrated in FIG. 11 for clarity, the phone board 1100 can include additional components and structures.

### Applications

Some of the embodiments described above have provided examples in connection with wireless devices or mobile phones. However, the principles and advantages of the embodiments can be used for any other systems or apparatus that have needs for filters.

Such filters can be implemented in various electronic devices. Examples of the electronic devices can include, but are not limited to, consumer electronic products, parts of the consumer electronic products, electronic test equipment, etc. Examples of the electronic devices can also include, but are not limited to, memory chips, memory modules, circuits of optical networks or other communication networks, and disk driver circuits. The consumer electronic products can include, but are not limited to, a mobile phone, a telephone, a television, a computer monitor, a computer, a hand-held computer, a personal digital assistant (PDA), a microwave, a refrigerator, an automobile, a stereo system, a cassette recorder or player, a DVD player, a CD player, a VCR, an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A filter device comprising:
a first node;
a second node;
a third node;
a transmit filter disposed between the first node and the second node to pass a transmit signal at a transmit band; and
a receive filter disposed between the second node and the third node to pass a receive signal at a receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than one, the length of the high aspect ratio resonator longer than 35 λ, λ being a wavelength of a resonant frequency of the high aspect ratio resonator.

2. The filter device of claim 1 wherein the filter device is one of a duplexer, a diplexer, and a multiplexer.

3. The filter device of claim 1 wherein the high aspect ratio resonator is directly connected to the second node in series.

4. The filter device of claim 3 wherein the second node is coupled to an antenna port.

5. The filter device of claim 1 wherein the width of the high aspect ratio resonator is longer than 16 λ and shorter than 24 λ, A being a wavelength of a resonant frequency of the high aspect ratio resonator.

6. The filter device of claim 1 wherein each of the transmit filter and the receive filter is a ladder-type band-pass filter.

7. The filter device of claim 1 wherein the high aspect ratio resonator includes a thin film surface acoustic wave resonator.

8. A radio frequency module comprising:
a packaging board configured to receive a plurality of components;
a filter device implemented on the packaging board, the filter device including: a first node; a second node; a third node; a transmit filter disposed between the first node and the second node to pass a transmit signal at a transmit band; and a receive filter disposed between the second node and the third node to pass a receive signal at a receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than one, the length of the high aspect ratio resonator longer than 35 λ, λ being a wavelength of a resonant frequency of the high aspect ratio resonator.

9. The radio frequency module of claim 8 wherein the radio frequency module is a front-end module.

10. The radio frequency module of claim 8 wherein the filter device is one of a duplexer, a diplexer, and a multiplexer.

11. The radio frequency module of claim 8 wherein the high aspect ratio resonator is directly connected to the second node in series.

12. The radio frequency module of claim 11 wherein the second node is coupled to an antenna port.

13. The radio frequency module of claim 8 wherein the width of the high aspect ratio resonator is longer than 16 λ and shorter than 24 λ, λ being a wavelength of a resonant frequency of the high aspect ratio resonator.

14. The radio frequency module of claim 8 wherein each of the transmit filter and the receive filter is a ladder-type band-pass filter.

15. The radio frequency module of claim 8 wherein the high aspect ratio resonator includes a thin film surface acoustic wave resonator.

16. A mobile device comprising:
a transceiver configured to generate a transmit signal and to process a receive signal; and
a filter device including: a first node; a second node; a third node; a transmit filter disposed between the first node and the second node to pass a transmit signal at a transmit band; and a receive filter disposed between the second node and the third node to pass a receive signal at an receive band, at least one of the transmit filter and the receive filter including a high aspect ratio resonator connected to the second node, the high aspect ratio resonator having an aspect ratio of a length in a propagation direction of the transmit signal or the receive signal and a width in an aperture direction perpendicular to the propagation direction higher than one, the length of the high aspect ratio resonator longer than 35 λ, λ being a wavelength of a resonant frequency of the high aspect ratio resonator.

17. The mobile device of claim 16 wherein the filter device is one of a duplexer, a diplexer, and a multiplexer.

18. The mobile device of claim 16 wherein the high aspect ratio resonator is directly connected to the second node in series, and the second node is coupled to an antenna port.

19. The mobile device of claim 16 wherein the width of the high aspect ratio resonator is longer than 16 λ and shorter than 24 λ, λ being a wavelength of a resonant frequency of the high aspect ratio resonator.

20. The mobile device of claim 16 wherein the high aspect ratio resonator includes a thin film surface acoustic wave resonator.
